(19) United States
(12) Patent Application Publication
(10) Pub. No.: US 2024/0258218 A1
(43) Pub. Date: Aug. 1, 2024

(54) SEMICONDUCTOR PACKAGE DEVICE AND METHOD FOR FORMING THE SAME

(71) Applicant: InnoLux Corporation, Miao-Li County (TW)

(72) Inventors: Cheng-Chi WANG, Miao-Li County (TW); Kuan-Hsueh LIN, Miao-Li County (TW); Shih-Kang LIN, Miao-Li County (TW)

(21) Appl. No.: 18/402,897

(22) Filed: Jan. 3, 2024

(30) Foreign Application Priority Data
Jan. 29, 2023 (CN) 202310081866.9
Dec. 5, 2023 (TW) 112147142

(51) Int. Cl. H01L 23/498; H01L 21/48; H01L 23/00; H01L 23/31

(52) U.S. Cl. CPC H01L 23/49811; H01L 21/4853; H01L 23/3128; H01L 24/13; H01L 24/16; H01L 24/81; H01L 2224/13147; H01L 2224/16227; H01L 2224/81385; H01L 2224/81405; H01L 2224/81455

(57) ABSTRACT

A semiconductor package device is provided. The semiconductor package device includes a circuit substrate having a first terminal end; a chip disposed on the circuit substrate and having a conductive pad; an auxiliary structure disposed between the first terminal end and the conductive pad, wherein the chip is electrically connected to the circuit substrate through the auxiliary structure; and a protective layer disposed on the circuit substrate and surrounding the chip, wherein the width of the first terminal end is greater than or equal to the width of the auxiliary structure.

### CROSS REFERENCE TO RELATED APPLICATIONS

This application claims priority of China Patent Application No. 202310081866.9, filed on Jan. 29, 2023, and Taiwan Patent Application No. 112147142, filed on Dec. 5, 2023 the entirety of which is incorporated by reference herein.

### BACKGROUND OF THE INVENTION

### Field of the Invention

The present disclosure relates to a semiconductor technology, in particular to a semiconductor package device and a method for forming the same.

### Description of the Related Art

In order to meet the needs of consumers, the semiconductor industry strives to integrate more components into a given area to increase a functional density of an electronic device. A small area semiconductor package device is beneficial to achieve goal of increasing the functional density of the electronic device.

A semiconductor package device includes stacked chips and circuit substrates. At present, the stacked chips and circuit substrates are mostly electrically connected to each other by a reflow soldering process. The reflow soldering process uses a solder paste and/or a solder ball to connect a conductive pad of the chip and a terminal end of the circuit substrate, and uses a heating process to form an intermetallic compound (IMC) from the solder paste and/or the solder ball between the conductive pad of the chip and the terminal end of the circuit substrate to electrically connect the chip and the circuit substrate. However, the intermetallic compound is a brittle material that will be easily broken and thus affect the reliability of the electronic device.

### BRIEF SUMMARY OF THE INVENTION

In view of the above problems, the present disclosure provides a semiconductor package device and a method for forming the same.

An embodiment of the present disclosure provides a semiconductor package device includes: a circuit substrate having a first terminal end; a chip disposed on the circuit substrate and having a conductive pad; an auxiliary structure disposed between the first terminal end and the conductive pad, wherein the chip is electrically connected to the circuit substrate through the auxiliary structure; and a protective layer disposed on the circuit substrate and surrounding the chip, wherein the width of the first terminal end is greater than or equal to the width of the auxiliary structure.

An embodiment of the present disclosure provides a method for forming a semiconductor package device. The method includes providing a circuit substrate and a chip; forming an auxiliary material pattern on the circuit substrate and/or the chip; forming an auxiliary structure between the circuit substrate and the chip; and forming a protective layer on the circuit substrate and surrounding the chip.

### BRIEF DESCRIPTION OF THE DRAWINGS

The present disclosure can be more fully understood by reading the subsequent detailed description and examples with references made to the accompanying drawings, wherein:

FIG. 1 shows a cross-sectional schematic view of a semiconductor package device according to an embodiment of the present disclosure.

FIG. 2 shows a cross-sectional schematic view of a semiconductor package device according to another embodiment of the present disclosure.

FIG. 3 shows a cross-sectional schematic view of a semiconductor package device according to another embodiment of the present disclosure.

FIG. 4 shows a cross-sectional schematic view of a semiconductor package device according to another embodiment of the present disclosure.

FIG. 5 shows a cross-sectional schematic view of a semiconductor package device according to another embodiment of the present disclosure.

FIG. 6 shows a cross-sectional schematic view of a semiconductor package device according to another embodiment of the present disclosure.

FIG. 7 is a flowchart of a method for forming a semiconductor package device according to an embodiment of the present disclosure.

FIG. 8 shows a schematic diagram of a first terminal top surface after a roughening process.

### DETAILED DESCRIPTION OF THE INVENTION

The following is a detailed description of elements of some embodiments of the present disclosure. It should be understood that, in the following description, various embodiments and examples are provided in order to implement the different aspects of some embodiments of the present disclosure. The specific elements and arrangements described in the following description are set forth in order to describe some embodiments of the present disclosure in a clear and easy manner. Of course, these are only used as examples but not as limitations of the present disclosure. In addition, repeated symbols or labels may be used in different embodiments. These repetitions are made only for the purpose of briefly and clearly describing some embodiments of the present disclosure and do not imply any correlation between the different embodiments and/or structures discussed. Furthermore, when a first material layer is described as being on or above a second material layer, the description includes situations where the first material layer is in direct contact with the second material layer. Alternatively, the description may include situations where there are one or more other material layers spaced apart the first material layer and the second material layer. In these situations, the first material layer may not be in direct contact with the second material layer.

In the disclosure, the terms “approximate,” “about,” and “approximately” usually indicates a value of a given value or range that varies within 10%, or within 5%, or within 3%, or within 2%, or within 1%, or within 0.5%. The value given here are approximate value, i.e., “approximate,” “about,” or “approximately” may be implied without specifying “approximate,” “about,” or “approximately”. In the disclosure, the term “a-b” indicates a value which is greater than or equal to a and less than or equal to b. In the disclosure, the term “less than or equal to” indicates a specific range including a given value and values below the given value, and the term “greater than or equal to” indicates a specific range including a given value and values above the given value. Conversely, the term “less than” indicates a specific range including values below the given value but not including the given value, and the term “greater than” indicates a specific range including values above the given value but not including the given value. For example, the term “greater than or equal to a” indicates a specific range including a and values above a, and “greater than a” indicates a specific range including values above a but not a.

It should be understood that, although the terms “first”, “second”, “third” etc. are used herein to describe various elements, components, area, layer, or parts, these elements, components, area, layer, or parts should not be limited by these terms. These terms are only used to distinguish one elements, components, area, layer, or parts from other elements, components, area, layer, or parts. Thus, a first element, component, area, layer, or part discussed below could be termed as a second element, component, area, layer, or part without departing from the teachings of the present disclosure.

It should be understood that relative terms such as “under”, “on”, “horizontal”, “vertical”, “below”, “above”, “top”, “bottom”, etc. shall be construed to indicate orientations shown in the paragraph and the related accompanying drawings. The relative terms are used for explanatory purposes only and does not imply that the device described is manufactured or operated in a specific orientation. Unless otherwise defined, the terms such as “connect” and “interconnect” may indicate that the two structures are in direct contact, or that the two structures are not in direct contact and some other structure is located between them. The terms “connect” and “interconnect” may also include situations where both structures are movable, or where both structures are fixed.

Unless defined otherwise, all technical and scientific terms used herein have the same meaning as commonly understood by one of ordinary skills in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

An electronic device of the present disclosure may include a power module, a semiconductor package device, a semiconductor device, a display device, a backlight device, an antenna device, a sensing device, or a splicing device, but the present disclosure is not limited thereto. The electronic device maybe a bendable or flexible electronic device. The display device may be a non-self-luminous display device or a self-luminous display device. The antenna device may be a liquid crystal antenna or a non-liquid crystal antenna, the sensing device may be a sensing device for sensing capacitance, light, heat or ultrasonic, but the present disclosure is not limited thereto. The splicing device may include, for example, a display splicing device or an antenna splicing device, but the present disclosure is not limited thereto. It should be noted that the electronic device may be combinations of the foregoing, but the present disclosure is not limited thereto. A processes for the electronic devices in the present disclosure may be applied, for example, in a wafer-level package (WLP) process or a panel-level package (PLP) process, wherein the wafer-level package (WLP) process and/or the panel-level package (PLP) process may be a chip first process or a chip last RDL first process.

In some embodiments of the present disclosure, terms such as “surrounding” refer to that in a schematic cross-sectional schematic view, at least part of one element is disposed inside another element, and the other element may further contact the side surface of the element. For example, an element B surrounding an element A means that at least part of the element A is disposed and/or embedded in the element B, and the element B contacts at least a side surface of the element A.

Some embodiments of the present disclosure may be understood in conjunction with the drawings. The drawings of the embodiments of the present disclosure may also be regarded as a part of the description of the embodiments of the present disclosure. It should be understood that the drawings of the embodiments of the present disclosure are not shown in proportion to actual devices and elements. The shapes and thicknesses of the embodiments may be exaggerated in the drawings in order to clearly show the features of the embodiments of the present disclosure. In addition, the structures and devices in the drawings are schematically shown in order to clearly show the features of the embodiments of the present disclosure.

In this disclosure, the length, thickness, height, distance and width of an element may be measured by an optical microscope (OM), an electron microscope (such as scanning electron microscope (SEM)) or other methods, but the present disclosure is not limited thereto.

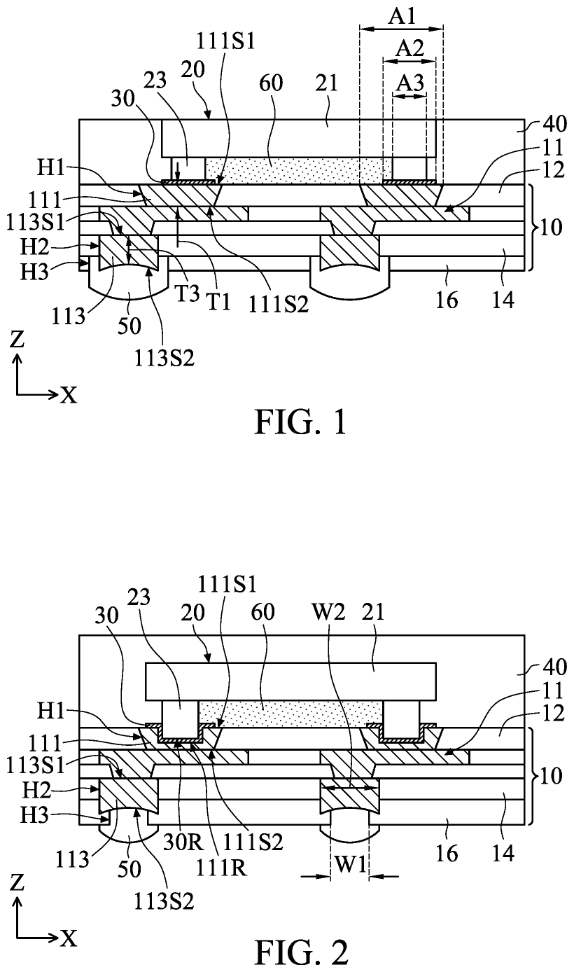

FIG. 1 shows a cross-sectional schematic view of a semiconductor package device according to an embodiment of the present disclosure. As shown in FIG. 1, the semiconductor package device of the present disclosure includes a circuit substrate 10, a chip 20 disposed on the circuit substrate 10, an auxiliary structure 30 disposed between the circuit substrate 10 and the chip 20, and a protective layer 40 disposed on the circuit substrate 10 and surrounding the chip 20. In some embodiments, the circuit substrate 10 and the chip 20 are stacked in a Z direction (i.e., the normal direction of the semiconductor package device of the present disclosure), and the auxiliary structure 30 is disposed between the circuit substrate 10 and the chip 20 in the Z direction.

The chip 20 may include a first electronic component 21 and a conductive pad 23. The first electronic component 21 may include passive elements or active elements, such as capacitors, resistors, inductors, diodes, transistors, sensors, drive circuit components, auxiliary/compensation circuit components, and the like. The diodes may include light-emitting diodes or photodiodes. The light-emitting diodes may include organic light-emitting diodes or inorganic light-emitting diodes. The light-emitting diodes may include, for example, organic light-emitting diodes (OLED), mini light-emitting diodes (mini LED), micro light-emitting diodes (micro LED), or quantum dot light-emitting diodes (quantum dot LED), but the present disclosure is not limited thereto. According to some embodiments, the chip 20 may further include a substrate (not shown). For example, a driving circuit or a compensation circuit may be disposed on the substrate to form the drive circuit components or the compensation circuit components. The substrate may include transparent or opaque organic materials or inorganic materials, and may also include rigid materials or flexible materials. The organic materials may include, for example, polyimides (PI), polycarbonates (PC), polyethylene terephthalates (PET), liquid crystal polymers (LCP), other known suitable materials, or combinations thereof, but the disclosure is not limited thereto. The inorganic materials may include dielectric materials or metal materials, but the present disclosure is not limited thereto. The rigid materials may include, for example, glasses, quartzs, sapphires, ceramics or plastics, or any suitable materials. Here, the term “flexible material” means that the material is able to be curved, bent, folded, rolled, flexed, stretched and/or other similarly deformed to present at least one of the above possible deformations. The flexible materials may include one of the above-mentioned organic materials, but the flexible materials of the present disclosure are not limited to the above-mentioned materials. The term “flexible” is not limited to being deformed by the above methods. The substrate may further include a through via (a through hole) penetrating the substrate in the normal direction of the substrate. The driving circuit, the compensation circuit, an optical fiber or a wire material may be disposed in the through hole, but the present disclosure is not limited thereto.

The conductive pad 23 is disposed under the first electronic component 21 and between the first electronic component 21 and the circuit substrate 10. The first electronic component 21 is electrically connected to the circuit substrate 10 through the conductive pad 23. In some embodiments, materials of the conductive pad 23 may include copper (Cu), aluminum (Al), molybdenum (Mo), tungsten (W), gold (Au), chromium (Cr), nickel (Ni), platinum (Pt), titanium (Ti), silver (Ag), other suitable metal materials, or combinations thereof.

The circuit substrate 10 may include a flexible substrate, a rigid substrate or a combination thereof, but the present disclosure is not limited thereto. The circuit substrate 10 may include a redistribution structure. In some embodiments, the redistribution structure (RDL structure) may be a stacked structure including a plurality of insulating layers and conductive patterns stacked in the Z direction. According to some embodiments, components may be electrically connected to each other through the redistribution structure. A fan-out capability of wires of the electronic device can improve by the redistribution structure. According to some embodiments, the circuit substrate 10 may include a carrier substrate, the substrate may include, for example, glasses, polyimides, silicones, sapphires, other suitable materials, or combinations thereof, but the disclosure is not limited thereto.

In some embodiments, as shown in FIG. 1, the redistribution structure includes a first insulating layer 12, a second insulating layer 14, a third insulating layer 16 and a conductive pattern 11 stacked in the Z direction. The first insulating layer 12 and the second insulating layer 14 may include the same or different materials. The first insulating layer 12 and the second insulating layer 14 may have a single-layer structure or a multi-layer stacked structure. Materials of the first insulating layer 12 and the second insulating layer 14 may include glass, silicon, nitrides, oxides, oxynitrides, perfluoroalkoxyalkanes (PFA), resins, photosensitive polyimides (PSPI), polyimides (PI), Ajinomoto build-up films (ABF), polybenzoxazoles (PBO), other suitable materials, or combinations thereof, but the disclosure is not limited thereto. In some embodiments, the materials of the first insulating layer 12 may include glass, silicon, silicon nitrides, silicon oxides, silicon oxynitrides, perfluoroalkoxyalkanes (PFA), or combinations thereof. In some embodiments, thicknesses of the first insulating layer 12 and the second insulating layer 14 in the Z direction may be the same or different. The thicknesses of the first insulating layer 12 and the second insulating layer 14 may be greater than or equal to 2 μm and less than or equal to 30 μm, but the disclosure is not limited thereto. The third insulating layer 16 is disposed on the second insulating layer 14. The second insulating layer 14 is disposed between the third insulating layer 16 and the first insulating layer 12. The third insulating layer 16 may include a solder resist (SR) layer. In some embodiments, thickness of the third insulating layer 16 may be the same as or different from the thicknesses of the first insulating layer 12 and the second insulating layer 14 in the Z direction. The thickness of the third insulating layer 16 may be greater than or equal to 20 μm and less than or equal to 40 μm.

The conductive pattern 11 includes a position disposed between the first insulating layer 12 and the second insulating layer 14, and the second insulating layer 14 is disposed between the position of the conductive pattern 11 and the third insulating layer 16. The second insulating layer 14 may include a second opening H2 and the third insulating layer 16 may include a third opening H3 overlapping the second opening H2 in the Z direction. The third opening H3 may include an opening width W1. In some embodiments, the opening width of the third opening H3 may be greater than an opening width of the second opening H2, but the disclosure is not limited thereto. The conductive pattern 11 may include a single conductive layer or multiple conductive layers. In some embodiments, as shown in FIG. 1, the conductive pattern 11 includes multiple conductive layers. Each conductive layer of the conductive layers may include the same or different materials. Materials of the conductive layer include seed layers, metals, or combinations thereof. In some embodiments, examples of the metals may include copper (Cu), aluminum (Al), molybdenum (Mo), tungsten (W), gold (Au), chromium (Cr), nickel (Ni), platinum (Pt), titanium (Ti), tantalum (Ta), titanium nitride (TiN), other suitable metal materials or a combination thereof. In some embodiments, the conductive pattern 11 may have a single-layer structure or a multi-layer stacked structure. For example, the conductive pattern 11 may include a single metal copper layer, or the conductive pattern 11 may include a metal titanium layer and a metal copper layer stacked in the Z direction, but the disclosure is not limited thereto. The material of the conductive pattern 11 may be formed using physical vapor deposition (PVD), atomic layer deposition (ALD), metalorganic chemical vapor deposition (MOCVD), an electroplating process, etching process, another suitable processing technique, or a combination thereof. In some embodiments, seed layer is in contact with the insulating layer will improve adhesion between the metal pattern/layer and the insulation layer, but not limited to.

In some embodiments, as shown in FIG. 1, the conductive pattern 11 may include a first terminal end 111 and a second terminal end 113. In other words, the circuit substrate 10 may include a plurality of first terminal ends 111 and a plurality of second terminal ends 113. The first terminal end 111 and the second terminal end 113 may be arranged on two opposite sides. The first terminal end 111 and the second terminal end 113 may electrically connected to each other. The first electronic component 21 may be electrically connected to the first terminal end 111 and the second terminal end 113 through the conductive pad 23. In some embodiments, as shown in FIG. 1, the redistribution structure has a first opening H1 penetrating through the first insulating layer 12. The first terminal end 111 may be disposed in the first opening H1, but the present disclosure is not limited thereto. In some embodiments, a portion of the first terminal end 111 may be disposed on the top surface of the first insulating layer 12. The above configuration may increase the reliability of the electronic device, for example, it may reduce the possibility of failing, but the disclosure is not limited thereto. In some embodiments, as shown in FIG. 1, the redistribution structure has a second opening H2 penetrating through the second insulating layer 14 and a third opening H3 penetrating through the third insulating layer 16. The second terminal end 113 may be disposed in the second opening H2 and the third opening H3, but the disclosure is not limited thereto. In some embodiments, a portion of the second terminal end 113 may be covered by the third insulating layer 16. Therefore, the risk of oxidation of the second terminal end 113 which is not covered by the subsequently formed connector 50 may be reduced. The second terminal end 113 may have a terminal width W2. In some embodiments, the terminal width W2 of the second terminal end 113 and the opening width W1 of the third opening H3 conform to the following formula: ½W2<W1<W2. When the terminal width W2 of the second terminal end 113 complies with the above formula, the risk of poor contact and electrical abnormalities caused by the second terminal end 113 being too small can be avoided. The electronic device may be connected to an external component through the second terminal end 113. The external component may include a printed circuit board (PCB), a carrier board or other suitable external components, but the disclosure is not limited thereto. In some embodiments, a portion of the second terminal end 113 may be disposed on a bottom surface of the second insulating layer 14. The first terminal end 111 and the second terminal end 113 may be disposed in the same or different ways. For example, in some embodiments, an entire of the first terminal end 111 may be disposed in the first opening H1 of the first insulating layer 12, and a portion of the second terminal end 113 may be disposed in the second opening H2 and the third opening H3 and a portion of the second terminal end 113 may be disposed on the bottom surface of the second insulating layer 14. The above configuration may increase a binding ability between the electronic device and the external component, but the disclosure is not limited thereto.

In some embodiments, a projection of the first terminal end 111 onto a plane (that is, the XY plane) perpendicular to the normal direction of the semiconductor package device may not overlap with a projection of at least one of the second terminal ends 113 onto the plane perpendicular to the normal direction of the semiconductor package device, but the disclosure is not limited thereto. In some embodiments, the projection of the first terminal end 111 onto the plane perpendicular to the normal direction of the semiconductor package device may overlap with the projection of the second terminal end 113 onto the plane perpendicular to the normal direction of the semiconductor package device. In some embodiments, at least one of the second terminal ends 113 does not overlap with one side of the chip 20. That is, the projection of the second terminal end 113 onto the plane perpendicular to the normal direction of the semiconductor package device may not overlap with a projection of the chip 20 onto the plane perpendicular to the normal direction of the semiconductor package device. In other words, at least one of the second terminal end 113 and one side of the chip 20 are misaligned with each other may reduce problems caused by a stress caused by bending the semiconductor package device.

The first terminal end 111 and the second terminal end 113 may have various shapes. The first terminal end 111 and the second terminal end 113 may have the same or different shapes. In some embodiments, the first terminal end 111 and the second terminal end 113 may have columnar structures, as shown in FIG. 1, but the disclosure is not limited thereto. In some embodiments, the first terminal end 111 has a first terminal top surface 111S1 and a first terminal bottom surface 111S2 opposite to the first terminal top surface 111S1. A distance between the first terminal top surface 111S1 and the first terminal bottom surface 111S2 in the Z direction is defined as a first thickness T1 of the first terminal end 111. The second terminal end 113 has a second terminal top surface 113S1 and a second terminal bottom surface 113S2 opposite to the second terminal top surface 113S1. A distance between the second terminal top surface 113S1 and the second terminal bottom surface 113S2 in the Z direction is defined as a second thickness T3 of the second terminal end 113. The first thickness T1 and the second thickness T3 may be the same as or different from each other. In some embodiments, the first thickness T1 may be smaller than the second thickness T3. In some embodiments, in a direction that is perpendicular to the Z direction, such as the X direction and/or the Y direction, the width of the first terminal top surface 111S1 may be greater than or equal to the width of the first terminal bottom surface 111S2, and the width of the second terminal bottom surface 113S2 may be greater than or equal to the width of the second terminal top surface 113S1. That is, a projection of the first terminal top surface 111S1 onto the plane perpendicular to the normal direction of the semiconductor package device may be greater than or equal to a projection of the first terminal bottom surface 111S2 onto the plane perpendicular to the normal direction of the semiconductor package device. A projection of the second terminal bottom surface 113S2 onto the plane perpendicular to the normal direction of the semiconductor package device may be greater than or equal to a projection of the second terminal top surface 113S1 onto the plane perpendicular to the normal direction of the semiconductor package device. The configuration in which a projection of a surface of the terminal end which is adjacent to the external component or other components is greater than a projection of a surface of the terminal end which is far away from the external component or other components, may improve the bonding ability, but the disclosure is not limited thereto.

The first terminal bottom surface 111S2 and the second terminal top surface 113S1 may be between the first terminal top surface 111S1 and the second terminal bottom surface 113S2. The first terminal top surface 111S1 may be exposed to outside and disposed between the first terminal bottom surface 111S2 and the conductive pad 23 of the chip 20. In some embodiments, as shown in FIG. 1, the second terminal bottom surface 113S2 may be exposed to outside, and a connecting member 50 may be disposed on the second terminal bottom surface 113S2. The connecting member 50 may directly contact the second terminal bottom surface 113S2 and electrically connect with the circuit substrate 10 through the second terminal end 113. In some embodiments, the connecting member 50 and the chip 20 may be disposed on different surfaces of the circuit substrate 10. The connecting member 50 may include a bump, a pad, a solder ball, or other suitable connecting components. The connecting member 50 may include copper (Cu), tin (Sn), nickel (Ni), gold (Au), lead (Pb), silver (Ag), gallium (Ga), other suitable metal materials or combinations thereof, but the disclosure is not limited thereto. The electronic device may be connected to a circuit board (PCB) or other external components through the connecting member 50.

In some embodiments, the first terminal top surface 111S1 and/or the second terminal bottom surface 113S2 may be a flat surface, a convex surface, a concave surface, or an irregular surface. The concave surface or irregular surface may improve an alignment between the conductive element such as the conductive pad 23 or the connecting member 50 and the first terminal top surface 111S1 and/or the second terminal bottom surface 113S2 and/or improve a binding strength between the conductive pad 23 and the first terminal end 111 or between the connecting member 50 and the second terminal end 113. The first terminal top surface 111S1 and the second terminal bottom surface 113S2 may have the same or different types of surfaces. In an embodiment, the first terminal top surface 111S1 may be a flat surface and the second terminal bottom surface 113S2 may be a concave surface, as shown in FIG. 1, but the disclosure is not limited thereto.

In some embodiments, the first terminal top surface 111S1, the first terminal bottom surface 111S2, and/or a first terminal side surface connecting the first terminal top surface 111S1 and the first terminal bottom surface 111S2 may have a high surface roughness. The high surface roughness may enhance the binding strength between the conductive pad 23 and the first terminal end 111. The surface roughness of the first terminal top surface 111S1, the first terminal bottom surface 111S2, and/or a first terminal side surface connecting the first terminal top surface 111S1 and the first terminal bottom surface 111S2 may be the same as of different each other. In some embodiments, the surface roughness of at least one of the first terminal top surface 111S1 is different from the surface roughness of at least one of the second terminal bottom surface 113S2. In some embodiments, the surface roughness of at least one of the first terminal top surface 111S1, the first terminal bottom surface 111S2, and the first terminal side surface connecting the first terminal top surface 111S1 and the first terminal bottom surface 111S2 may be greater than that of the second terminal top surface 113S1, the second terminal bottom surface 113S2, and/or a second terminal side surface connecting the second terminal top surface 113S1 and the second terminal bottom surface 113S2. It should be understood that, the roughness (Rz) of the surface may be defined as a value obtained by using, for example, a scanning electron microscope or other suitable instruments to obtain local roughness of at least ten points on the surface and calculating according to the following formula:

$${R}_{z} = \frac{1}{5} {\sum }_{t = 1}^{5} {R}_{p t} - {R}_{v t}$$

in the formula, Rₚₜ is a local roughness at a protrusion and Rᵥₜ is a local roughness at a depression.

The first terminal end 111 and the second terminal end 113 may include the same or different materials. The first terminal end 111 and the second terminal end 113 may include a seed layer, a metal, or combinations thereof. In some embodiments, the first terminal end 111 and the second terminal end 113 may include copper (Cu), aluminum (Al), molybdenum (Mo), tungsten (W), gold (Au), chromium (Cr), nickel (Ni), platinum (Pt), titanium (Ti), other suitable metal materials or combinations thereof. In some embodiments, materials of the first terminal end 111 and the second terminal end 113 may include copper (Cu).

The auxiliary structure 30 is disposed between the first terminal end 111 and the conductive pad 23. In some embodiments, the auxiliary structure 30 is in direct contact with the first terminal end 111 and the conductive pad 23. The chip 20 is electrically connected to the circuit substrate 10 through the auxiliary structure 30.

In the direction perpendicular to the Z direction, such as the X direction and/or the Y direction, the width A3 of the conductive pad 23 may be smaller than the width A2 of the auxiliary structure 30, and the width A2 of the auxiliary structure 30 may be smaller than the width A1 of the first terminal end 111. In some embodiments, a projection of the conductive pad 23 onto the plane (i.e., the XY plane) perpendicular to the normal direction of the semiconductor package device may be smaller than a projection of the auxiliary structure 30 onto the plane perpendicular to the normal direction of the semiconductor package device. The projection of the auxiliary structure 30 onto the plane perpendicular to the normal direction of the semiconductor package device may be smaller than the projection of the first terminal end 111 onto the plane perpendicular to the normal direction of the semiconductor package device. Here, the width A1 of the first terminal end 111 refers the larger one of the widths of the first terminal top surface 111S1 and first terminal bottom surface 111S2 in a direction perpendicular to the Z direction, such as the X direction and/or the Y direction.

The auxiliary structure 30 includes a solid solution compound. In an embodiment, the auxiliary structure 30 may include a face centered cubic (FCC) type solid solution compound. The solid solution compound of the auxiliary structure 30 includes the material from the first terminal end 111 and/or the conductive pad 23 and any material that may be solid-solved with the material of the first terminal end 111 and/or the conductive pad 23. The solid solution compound has properties similar to those of the first terminal end 111 and the conductive pad 23, so as to improve the binding strength between the first terminal end 111 and the conductive pad 23 and/or improve the reliability of the semiconductor package device. In some embodiments, the first terminal end 111 and/or the conductive pad 23 includes copper, and the solid solution compound of the auxiliary structure 30 may include copper from the first terminal end 111 and/or the conductive pad 23 and gallium (Ga), but the disclosure is not limited thereto. In some embodiments, the solid solution compound of the auxiliary structure 30 may further include nickel (Ni). Nickel may further enhance the binding strength between the first terminal end 111 and the conductive pad 23 and/or improve the reliability of the semiconductor package device.

The auxiliary structure 30 has a thickness in the Z direction (i.e., the normal direction of the semiconductor package device of the present disclosure). In some embodiments, the thickness of the auxiliary structure 30 is about 3-10 μm. Disposing the auxiliary structure 30 between the first terminal end 111 and the conductive pad 23 may improve the binding strength between the chip 20 and the circuit substrate 10 while reduce a distance between the chip 20 and the circuit substrate 10. In some embodiments, a shearing force of the auxiliary structure 30 may be about 3-20 MPa. In some embodiments, a melting point of the auxiliary structure 30 may be lower than a melting point of the first terminal end 111 and/or the conductive pad 23. The auxiliary structure 30, the first terminal end 111 and the conductive pad 23 may include crystal grains. In some embodiments, a grain size of the grains in the auxiliary structure 30 may be smaller than a grain size of the grains in the first terminal end 111 and/or the conductive pad 23. The shearing force in the present disclosure may be measured by, for example, ASTM D1002 test method or measured by a universal testing machine or other suitable testing equipment, but the disclosure is not limited thereto.

The protective layer 40 is disposed on the circuit substrate 10. The protective layer 40 may surround the chip 20 to prevent moisture and oxygen from an external environment from entering the chip 20, thereby improving the reliability and a service life of the semiconductor package device. The protective layer 40 may include organic materials, inorganic materials, and combinations thereof. Examples of the organic materials may include silicone resins, acrylic resins, and epoxy resins, but the disclosure is not limited thereto. Examples of the inorganic materials may include silicon nitrides (SiNx), silicon oxides (SiOx), silicon oxynitrides (SiONx), aluminum oxides (AlOx), or titanium oxides (TiOx), but the disclosure is not limited thereto. In some embodiments, the protective layer 40 may further include first filler particles 40P.

In some embodiments, the semiconductor package device may further include an intermediate layer 60. The intermediate layer 60 may be, for example, an underfill. The intermediate layer 60 is disposed between the circuit substrate 10 and the chip 20. The intermediate layer 60 may include organic materials, but the present disclosure is not limited thereto. The organic materials may include epoxy resins, acrylic resins, or other suitable materials. In some embodiments, the intermediate layer 60 may include second filler particles. In some embodiments, the particle size of the second filler particle is smaller than that of the first filler particle. The first filler particles and/or the second filler particles may increase a mechanical strength of the protective layer 40 and/or the intermediate layer 60, and improve the reliability of the semiconductor package device. By making the particle size of the second filler particle smaller than that of the first filler particle, the chip may be closer to the circuit substrate, the electronic device may pass a severe drop test (Drop test) and a rolling test (Tumble test), but the present disclosure is not limited thereto. In some embodiments, the particle size may be an average value. For example, in a cross-sectional view OM or SEM, take the same area (for example, a square of 1 cm*1 cm) for the protective layer and intermediate layer respectively, calculate the average particle size of the complete particles in the square, and compare.

The materials of the first filler particles and the second filler particles may include organic materials or inorganic materials. Examples of the inorganic materials may include glass fibers, carbon fibers, metal oxides, silicon dioxides, calcium carbonates, or combinations thereof, but the present disclosure is not limited thereto. Examples of the organic materials may include polytetrafluoroethylenes, polyphenylene sulfides, polyetherimides, polyphenylene oxides, polyethersulfides, or combinations thereof, but the disclosure is not limited thereto.

The first filler particles and the second filler particles may include the same or different materials. The first filler particle has a maximum particle size, and the second filler particle has a maximum particle size. Here, the “maximum particle size” refers to a maximum length of a projection of the first filler particle and/or the second filler particle on the ZX plane in the Z direction.

The first terminal end 111 of the circuit substrate 10 and the auxiliary structure 30 will be further described below with reference to FIG. 2. As shown in FIG. 2, the first terminal end 111 in the circuit substrate 10 is formed in the first opening H1, and the first terminal end 111 formed in the first opening H1 has a terminal groove 111R. The auxiliary structure 30 may be conformally formed in the terminal groove 111R in the first opening H1. The auxiliary structure 30 formed in the terminal groove 111R has an auxiliary structure groove 30R, as shown in FIG. 2. The width A2 of the auxiliary structure 30 may be smaller than the width A1 of the first terminal end 111.

In some embodiments, the conductive pad 23 may be smaller than the auxiliary structure groove 30R. A portion of the conductive pad 23 may be embedded in the auxiliary structure groove 30R of the auxiliary structure 30, as shown in FIG. 2. In this embodiment, the alignment of the conductive pad 23 and the auxiliary structure 30 and/or the first terminal end 111 is better, the binding strength between the first terminal end 111 and the conductive pad 23 may be improved, and/or the electrical connection between the chip 20 and the circuit substrate 10 is more stable, and thus, a signal transmission quality between the chip 20 and the circuit substrate 10 will be improved.

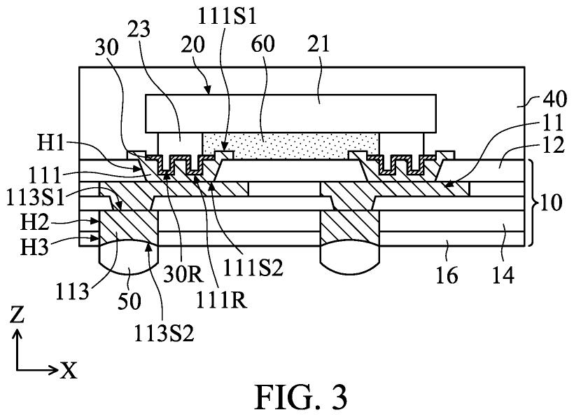

FIG. 3 is a schematic cross-sectional view of a semiconductor package device according to another embodiment of the disclosure. Except that the shapes of the first terminal end 111 in the redistribution structure of the circuit substrate 10 and the auxiliary structure 30, the rest of the components in the semiconductor package device shown in FIG. 3 are substantially the same as the components described in the semiconductor package device shown in FIG. 2, so they will not be repeated here.

The first terminal end 111 of the circuit substrate 10 and the auxiliary structure 30 will be further described below with reference to FIG. 3. As shown in FIG. 3, the first terminal end 111 in the circuit substrate 10 is formed in the first opening H1 and has two terminal grooves 111R. The auxiliary structure 30 may be conformally formed in the terminal grooves 111R in the first opening H1. The auxiliary structure 30 formed in the terminal grooves 111R has two auxiliary structure grooves 30R, as shown in FIG. 3. The width A2 of the auxiliary structure 30 may be smaller than the width A1 of the first terminal end 111.

In some embodiments, the conductive pad 23 may be larger than the auxiliary structure grooves 30R. The conductive pad 23 may be formed on the auxiliary structure grooves 30R and cover the auxiliary structure grooves 30R, but the disclosure is not limited thereto. In some embodiments, a portion of the conductive pad 23 may be embedded in the auxiliary structure grooves 30R and surrounded by the auxiliary structure 30. In this embodiment, the binding strength between the first terminal end 111 and the conductive pad 23 may be improved, and/or the electrical connection between the chip 20 and the circuit substrate 10 may be more stable, and thus, the signal transmission quality between the chip 20 and the circuit substrate 10 will be improved.

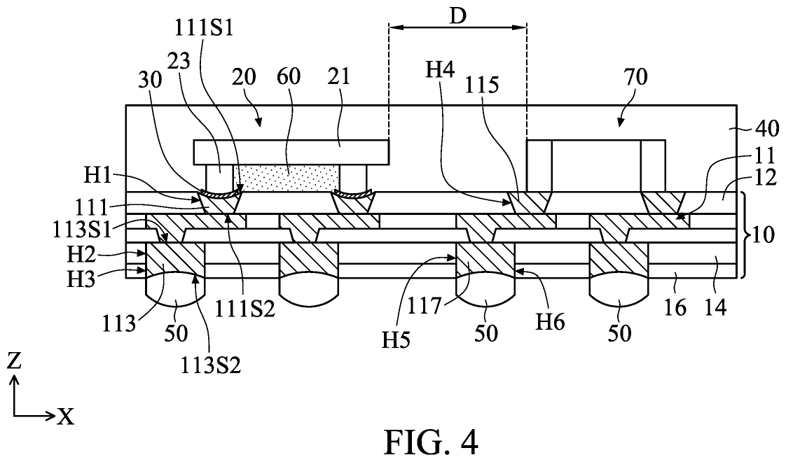

FIG. 4 is a cross-sectional schematic view of a semiconductor package device according to another embodiment of the present disclosure. As shown in FIG. 4, the semiconductor package device of the present disclosure includes a circuit substrate 10, a chip 20 disposed on the circuit substrate 10, a second electronic component 70 disposed on the circuit substrate 10, an auxiliary structure 30 disposed between the circuit substrate 10 and the chip 20, and the protective layer 40. Except for the second electronic component 70 and the redistribution structure, the rest of the components in the semiconductor package device shown in FIG. 4 are substantially the same as those described in the semiconductor package device shown in FIG. 1, so they will not be repeated here. The second electronic component in the present disclosure may include, for example, a surface mount device (SMD), an integrated circuit chip, a diode, a driving circuit, a compensation circuit, an integrated passive device (IPD) or other suitable components, but the disclosure is not limited thereto. The electronic components in the present disclosure may further include a carrier substrate.

The redistribution structure in the circuit substrate 10 includes a first insulating layer 12, a second insulating layer 14, and a conductive pattern 11 stacked in the Z direction. The conductive pattern 11 includes a first terminal end 111, a second terminal end 113, a third terminal end 115, and a fourth terminal end 117. The first insulating layer 12 has a first opening H1 and a fourth opening H4, and the second insulating layer 14 has a second opening H2 and a fifth opening H5. The first terminal end 111 and the third terminal end 115 are respectively disposed in the first opening H1 and the fourth opening H4 in a columnar structure. The second terminal end 113 and the fourth terminal end 117 are respectively disposed in the second opening H2 and the fifth opening H5 in a columnar structure. The first terminal end 111 and the second terminal end 113 are electrically connected to each other, and the third terminal end 115 and the fourth terminal end 117 are electrically connected to each other. In some embodiments, the first terminal end 111 and the second terminal end 113 are insulated from the third terminal end 115 and the fourth terminal end 117, but the disclosure is not limited thereto.

In some embodiments, the redistribution structure includes a third insulating layer 16. The second insulating layer 14 is disposed between the third insulating layer 16 and the first insulating layer 12, as shown in FIG. 4. The third insulating layer 16 may include a third opening H3 and a sixth opening H6. In the Z direction, the second opening H2 overlaps the third opening H3 and the fifth opening H5 overlaps the sixth opening H6. The second terminal end 113 is disposed in the second opening H2 and the third opening H3, and the fourth terminal end 117 is disposed in the fifth opening H5 and the sixth opening H6.

In some embodiments, the chip 20 and the second electronic component 70 are disposed on the first insulating layer 12, as shown in FIG. 4, but the disclosure is not limited thereto. In some embodiments, the semiconductor package device of the present disclosure may include multiple second electronic components 70. The second electronic components 70 may be on both sides of the chip 20 or surround the chip 20. In a direction perpendicular the Z direction, a width of the second electronic component 70 may be greater than or equal to a distance D between the chip 20 and the second electronic component 70. In some embodiments, the distance D may be greater than 1 mm to avoid the risk of signal interference or shielding. The chip 20 is electrically connected to the first terminal end 111, and the connecting member 50 is electrically connected to the second terminal end 113. In an embodiment, the first terminal top surface 111S1 of the first terminal end 111 and the second terminal bottom surface 113S2 of the second terminal end 113 are concave surfaces. The shapes of the conductive pad 23 and the auxiliary structure 30 correspond to the first terminal top surface 111S1 and the shape of the connecting member 50 corresponds to the second terminal bottom surface 113S2, as shown in FIG. 4. The second electronic component 70 is electrically connected to the third terminal end 115, and the other connecting member 50 is electrically connected to the fourth terminal end 117. The protective layer 40 surrounds the chip 20 and the second electronic component 70 and covers the surfaces of the chip 20 and the second electronic component 70.

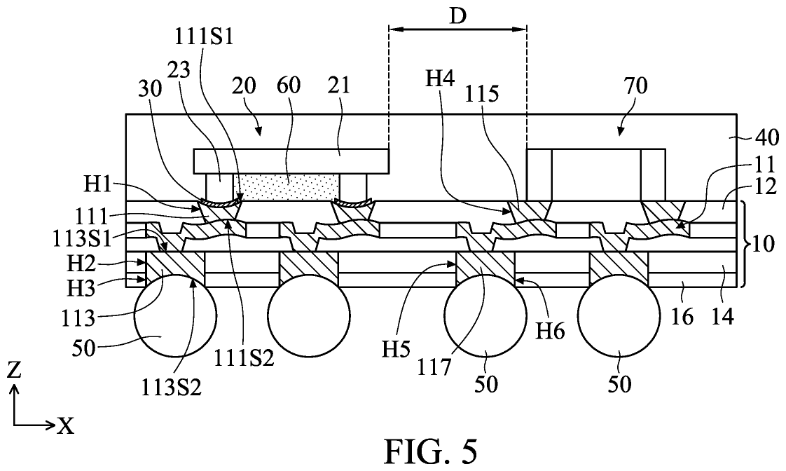

FIG. 5 is a schematic cross-sectional view of a semiconductor package device according to another embodiment of the disclosure. Except that the portion of the conductive pattern 11 in disposed between the first insulating layer 12 and the second insulating layer 14 has a recess and a wavy edge, the structure of the semiconductor packaging device shown in FIG. 5 is substantially the same as that of the semiconductor packaging device shown in FIG. 4. The position of the recess of the conductive pattern 11 may correspond to the second terminal end 113, but the present disclosure is not limited thereto.

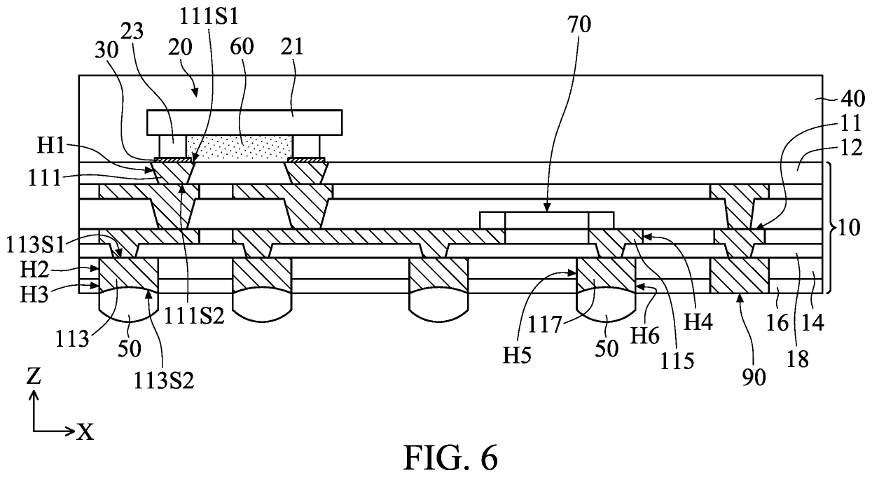

FIG. 6 is a schematic cross-sectional view of a semiconductor package device according to another embodiment of the disclosure. As shown in FIG. 6, the semiconductor package device of the present disclosure includes a circuit substrate 10, a chip 20 disposed on the circuit substrate 10, a second electronic component 70 disposed in the circuit substrate 10, and an auxiliary structure 30 disposed between the circuit substrate 10 and the chip 20, and a protective layer 40. Except that the redistribution structure further includes an intermediate insulating layer 18 between the first insulating layer 12 and the second insulating layer 14; and the second electronic component 70 is disposed on the intermediate insulating layer 18, disposed between the first insulating layer 12 and the second insulating layer 14, and electrically connected with the chip 20, the rest of the components in the semiconductor package device shown in FIG. 4 are substantially the same as the components described in the semiconductor package device shown in FIG. 6, so they will not be repeated here.

In some embodiments, as shown in FIG. 6, the conductive pattern 11 may further include a connecting pattern 90 for connecting other electronic components or using as a tracing pattern or an alignment mark, but the disclosure is not limited thereto.

The above-mentioned FIGS. 1 to 5 provide a semiconductor package device including a circuit substrate having a first terminal end, a chip disposed on the circuit substrate and having a conductive pad, an auxiliary structure disposed between the first terminal end and the conductive pad and electrically connected to the chip and the circuit substrate, and protective layer disposed on the circuit substrate and surrounding the chip. In the direction perpendicular to the normal direction of the semiconductor package device, the width of the auxiliary structure is less than or equal to the width of the first terminal end. The semiconductor package device has good binding strength and/or improved signal transmission quality. Therefore, the semiconductor package device has improved reliability. The semiconductor package device may be integrated into an electronic device to improve the reliability of the electronic device.

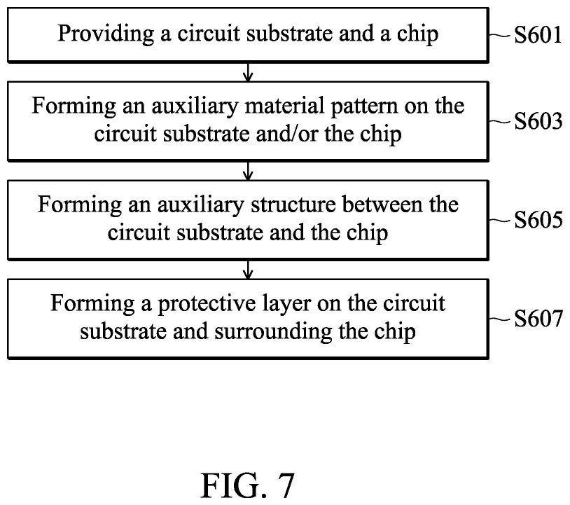

Another aspect of the present disclosure provides a method for forming a semiconductor package device. FIG. 7 is a flowchart of a method for forming a semiconductor package device according to an embodiment of the present disclosure. As shown in FIG. 7, the method includes: a step S601 of providing a circuit substrate and a chip; a step S603 of forming an auxiliary material pattern on the circuit substrate and/or the chip; a step S605 of forming an auxiliary structure between the circuit substrate and the chip; and a step S607 of forming a protective layer on the circuit substrate and surrounding the chip. The method for forming the semiconductor package device of the present disclosure is further described below with FIG. 1 to FIG. 6.

In the step S601, a circuit substrate 10 having a first terminal end 111 and a chip 20 having a conductive pad 23 are provided. The specific structures of the circuit substrate 10 and the chip 20 have been described above with reference to FIG. 1 to FIG. 6, so details thereof will not be repeated here.

In the step S603, the auxiliary material pattern is formed on the circuit substrate 10 and/or the chip 20. More specifically, the auxiliary material pattern is formed on the first terminal end 111 of the circuit substrate 10 and/or on the conductive pad 23 of the chip 20. A projection of the auxiliary material pattern onto a plane (XY plane) perpendicular to the normal direction of the circuit substrate 10 (Z direction) may be smaller than a projection of the first terminal end 111 onto the plane perpendicular to the normal direction of the circuit substrate 10. The projection of the auxiliary material pattern onto the plane (XY plane) perpendicular to the normal direction of the circuit substrate 10 (Z direction) may be larger than a projection of the conductive pad 23 onto a plane perpendicular to the normal direction of the circuit substrate 10.

The step S603 may include a step of forming an auxiliary material layer including an auxiliary material on the circuit substrate 10 and/or the chip 20 and a step of patterning the auxiliary material layer to form the auxiliary material pattern. The auxiliary material may include any material which is able to be solid-solved with the material of first terminal end 111 and/or the conductive pad 23. In some embodiments, the auxiliary material layer may include a single-layer or multiple-layer structure with a thickness of 10 nm-1000 nm, or 20 nm-500 nm, or 30 nm-300 nm. In an embodiment where the first terminal end 111 and/or the conductive pad 23 includes copper, the auxiliary material layer may be a single-layer structure including a single gallium layer or a double-layer structure including a stack of a gallium layer and a nickel layer. In an embodiment where the auxiliary material layer is a double-layer structure including a stack of a gallium layer and a nickel layer, the nickel layer may be disposed between the gallium layer and the first terminal end 111 and/or the conductive pad 23. The step of forming the auxiliary material layer may include any conventionally available methods. For example, the step of forming the auxiliary material layer may include a physical deposition method, a chemical deposition method, or a combination thereof. Examples of the physical deposition method may include a vacuum evaporation method, a sputter plating method, a atomic layer deposition method, an ion plating method, etc., but the present disclosure is not limited thereto. Examples of the chemical deposition method may include an electroplating method, a chemical vapor deposition method, a plasma chemical vapor deposition method, etc., but the present disclosure is not limited thereto. In some embodiments, the auxiliary material layer is formed on an entire surface of the circuit substrate 10 and/or the chip 20 by an electroplating method.

The step of patterning the auxiliary material layer may include any conventionally available methods. For example, the step of patterning the auxiliary material layer may include a photolithography process, a dry etching process, a wet etching process, a micro-etching process, or combinations thereof. Examples of the dry etching process may include a plasma etching method, a reactive ion etching method, a plasma etching method, a laser etching method, etc., but the disclosure is not limited thereto. Examples of the wet etching process may include a chemical etching method, etc., but the disclosure is not limited thereto. In this step, the auxiliary material layer formed outside the first terminal end 111 of the circuit substrate 10 and/or the conductive pad 23 of the chip 20 may be removed to form an auxiliary material pattern. A temperature in the step of patterning the auxiliary material layer may be lower than a melting point of the auxiliary material. Therefore, the auxiliary material layer may be remained on a desired position (i.e., on the first terminal end 111 of the circuit substrate 10 and/or on the conductive pad 23 of the chip 20) to form the auxiliary material pattern.

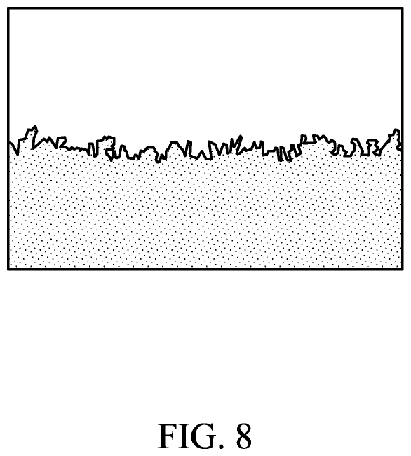

In some embodiments, in order to make the surface roughness of any one of the first terminal top surface 111S1, the first terminal bottom surface 111S2, or the first terminal side surface connecting the first terminal top surface 111S1 and the first terminal bottom surface 111S2 of the first terminal end 111 greater than surface roughness of the second terminal top surface 113S1, the second terminal bottom surface 113S2, and/or the second terminal side surface connecting the second terminal top surface 113S1 and the second terminal bottom surface 113S2 of the second terminal end 113, the method for forming a semiconductor package device may further include performing a roughening process on the first terminal end 111 before the step S603. A high surface roughness may enhance the binding strength between the conductive pad 23 and the first terminal end 111. In some embodiments, the roughening process may include a dry etching process, a wet etching process, or a combination thereof. Examples of the dry etching process and/or the wet etching process are described above and will not be repeated here. FIG. 8 is a schematic diagram of the first terminal top surface 111S1 of the first terminal end 111 after the roughening process, but the disclosure is not limited thereto. The first terminal bottom surface 111S2 and/or the first terminal side surface connecting the first terminal top surface 111S1 and the first terminal bottom surface 111S2 of the first terminal end 111 may also have rough surfaces similar to that shown in FIG. 8.

In the step S605, the first terminal end 111, the conductive pad 23, and the auxiliary material pattern are aligned. The auxiliary material pattern is in direct contact with the first terminal end 111 and the conductive pad 23. Next, a pressing process is performed to make the first terminal end 111 and/or the conductive pad 23 and the auxiliary material pattern solid-solved with each other and form an auxiliary structure including the materials form the first terminal end 111 and/or the conductive pad 23 and the material form the auxiliary material pattern. In some embodiments, the pressing process includes a process pressure of 1-10 MPa and a process temperature of 200-400° C. In an embodiment where the material of the first terminal end 111 and/or the conductive pad 23 includes copper, the auxiliary material may include gallium, and the auxiliary structure 30 formed after the pressing process may include copper and gallium, but the disclosure is not limited thereto. In some embodiments, the auxiliary material may include gallium and nickel, and the auxiliary structure 30 formed after the pressing process may include copper, nickel, and gallium. The auxiliary structure 30 includes materials from the first terminal end 111 and/or the conductive pad 23. Therefore, the auxiliary structure 30 may have properties similar to those of the first terminal end 111 and the conductive pad 23, thereby improving the a binding strength between the first terminal end 111 and the conductive pad 23 and improving the reliability of the semiconductor package device.

In some embodiments, the intermediate layer 60 is formed before or at the same time as the step S605. The intermediate layer 60 may include organic materials, but the present disclosure is not limited thereto. The organic materials include epoxy resins, acrylic resins, or other suitable materials. In some embodiments, the intermediate layer 60 may include second filler particles. The formation of the intermediate layer may include a coating process, a bonding process, a curing process, a capillary process or other suitable processes. In some embodiments, a step of forming the second electronic component 70 and/or the connecting pattern 90 may be further included before the step S607.

In the step S607, a protective layer 40 is formed on the circuit substrate 10 and surrounding the chip 20, the second electronic component 70, and/or the connecting pattern 90. In some embodiments, the protective layer 40 may cover the chip 20 and/or the second electronic component 70, but the disclosure is not limited thereto. The step of forming the protective layer 40 may include a transfer molding process, a compression molding process or other suitable processes. The protective layer 40 may prevent the chip 20, the second electronic component 70, and/or the connecting pattern 90 from being affected by moisture and/or oxygen in the environment, thereby improving the reliability and/or service life of the semiconductor package device of the present disclosure.

The protective layer 40 may include organic materials, inorganic materials, and combinations thereof. Examples of the organic materials may include silicone resins, acrylic resins, and epoxy resins, but the disclosure is not limited thereto. Examples of the inorganic materials may include silicon nitrides (SiNx), silicon oxides (SiOx), silicon oxynitrides (SiONx), aluminum oxides (AlOx), or titanium oxides (TiOx), but the disclosure is not limited thereto. In some embodiments, the protective layer 40 may further include first filler particles. The materials and properties of the first filler particles and the second filler particles are as described above, so they will not be repeated here. The first filler particles and/or the second filler particles may increase the mechanical strength of the protective layer 40 and/or the intermediate layer 60 and improve the reliability of the semiconductor package device.

To sum up, according to the above-mentioned method for forming a semiconductor package device of the present disclosure, the bonding strength between the circuit substrate and the chip in the semiconductor package device formed by the above-mentioned method is improved. Therefore, an electrical connection between the chip and the circuit substrate is more stable, the signal transmission quality between the chip and the circuit substrate is improved, and the reliability of the semiconductor package device is improved. The prepared semiconductor package device may also be integrated into an electronic device to improve the reliability of the electronic device.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package device, comprising:
a circuit substrate having a first terminal end;
a chip disposed on the circuit substrate and having a conductive pad;
an auxiliary structure disposed between the first terminal end and the conductive pad, wherein the chip is electrically connected to the circuit substrate through the auxiliary structure; and
a protective layer disposed on the circuit substrate and surrounding the chip,
wherein in a direction perpendicular to a normal direction of the semiconductor package device, the first terminal end has a first width, the auxiliary structure has a second width, and the first width is greater than or equal to the second width.

2. The semiconductor package device as claimed in claim 1, wherein, in the direction perpendicular to the normal direction of the semiconductor package device, the conductive pad has a third width, and the third width is smaller than the first width.

3. The semiconductor package device as claimed in claim 1, further comprising an intermediate layer disposed between the circuit substrate and the chip.

4. The semiconductor package device as claimed in claim 1, wherein the circuit substrate has a second terminal end, the second terminal end is opposite to the first terminal end, wherein the second terminal end and one side of the chip are misaligned with each other.

5. The semiconductor package device as claimed in claim 4, wherein the second terminal end has a concave surface.

6. The semiconductor package device as claimed in claim 4, wherein the first terminal end has a surface, the second terminal end has a surface, and a surface roughness of the surface of the first terminal end is different from a surface roughness of the surface of the second terminal end.

7. The semiconductor package device as claimed in claim 1, wherein a projection of the conductive pad onto a plane perpendicular to the normal direction of the semiconductor package device is smaller than a projection of the auxiliary structure onto the plane perpendicular to the normal direction of the semiconductor package device.

8. The semiconductor package device as claimed in claim 1, wherein the protective layer comprises first filler particles.

9. The semiconductor package device as claimed in claim 8, further comprising an intermediate layer disposed between the circuit substrate and the chip, and the intermediate layer comprises second filler particles.

10. The semiconductor package device as claimed in claim 9, wherein a particle size of the second filler particles is smaller than a particle size of the first filler particles.

11. The semiconductor package device as claimed in claim 1, further comprising an electronic component disposed on the circuit substrate.

12. The semiconductor package device as claimed in claim 1, further comprising an electronic component disposed in the circuit substrate.

13. A method for forming a semiconductor package device, comprising:
providing a circuit substrate and a chip;
forming an auxiliary material pattern on the circuit substrate, the chip, or a combination thereof;
forming an auxiliary structure between the circuit substrate and the chip; and
forming a protective layer on the circuit substrate and surrounding the chip.

14. The method for forming a semiconductor package device as claimed in claim 13, wherein the step of forming the auxiliary material pattern comprising a step of forming an auxiliary material layer comprising an auxiliary material on the circuit substrate, the chip, or a combination thereof and a step of patterning the auxiliary material layer to form the auxiliary material pattern.

15. The method for forming a semiconductor package device as claimed in claim 14, wherein the thickness of the auxiliary material layer is 20 nm-1000 nm.

16. The method for forming a semiconductor package device as claimed in claim 14, wherein the circuit substrate has a first terminal end, the chip has a conductive pad, the auxiliary material comprises a material which is able to be solid-solved with the materials of first terminal end, the conductive pad, or a combination thereof.

17. The method for forming a semiconductor package device as claimed in claim 16, wherein the first terminal end and the conductive pad comprise copper and the auxiliary material comprises gallium.

18. The method for forming a semiconductor package device as claimed in claim 17, wherein the auxiliary material further comprises nickel.

19. The method for forming a semiconductor package device as claimed in claim 13, further comprising performing a roughening process on the first terminal end before forming the auxiliary material pattern.

20. The method for forming a semiconductor package device as claimed in claim 13, wherein forming the auxiliary structure comprising performing a pressing process, and the pressing process includes a process pressure of 1-10 MPa and a process temperature of 200-400° C.
